(19) United States
(12) Patent Application Publication
(10) Pub. No.: US 2025/0385599 A1
(43) Pub. Date: Dec. 18, 2025

(54) APPARATUS FOR PROTECTING CIRCUIT FROM POWER CONVERTER SHORT CIRCUIT FAULT

(71) Applicant: HL MANDO CORPORATION, Pyeongtaek-si (KR)

(72) Inventors: YUTAE KIM, Pyeongtaek-si (KR); MANKYU LEE, Pyeongtaek-si (KR)

(73) Assignee: HL MANDO CORPORATION, Pyeongtaek-si (KR)

(21) Appl. No.: 19/229,697

(22) Filed: Jun. 5, 2025

(30) Foreign Application Priority Data
Jun. 13, 2024 (KR) 10-2024-0076736

(51) Int. Cl. H02M 1/32; H02M 3/158

(52) U.S. Cl. CPC H02M 1/32; H02M 3/158

(57) ABSTRACT

The present disclosure relates to a circuit apparatus for protecting control devices connected to a load from a short circuit fault of a power conversion device, and an apparatus for protecting circuit according to the present disclosure comprises a switch that controls the connection between nodes, and so if the output of the power conversion device is abnormal, the circuit is configured not to connect the switch so that the abnormal output of the power conversion device is not transmitted to the load, thereby protecting the control devices connected to the load even when the power conversion device fails.

### CROSS-REFERENCE TO RELATED APPLICATION

This application claims priority to and the benefit from Korean Patent Application No. 10-2024-0076736, filed on Jun. 13, 2024, the disclosures of which are incorporated herein by reference in its entirety.

### TECHNICAL FIELD

The present disclosure relates to a power conversion device, and in particular, to a technology capable of protecting a load in the event of a failure of the power conversion device.

### DESCRIPTION OF RELATED ART

A power conversion device is a device that literally converts the type or magnitude of power. In other words, it is a device that converts alternating current into direct current, direct current into alternating current, or converts the magnitude of voltage or current.

A converter is one of the representative power conversion device along with an inverter. The inverter receives alternating current and converts it into direct current and then converts it back into alternating current for motor control to control the electric motor. On the other hand, converters, especially DC-DC converters, are used to convert small DC voltages into larger DC voltages using switches with relatively small rated voltages.

### BRIEF SUMMARY

FIG. 6 shows an example of a circuit in which a converter is used among such power conversion devices. A buck converter, which is an example of a power conversion device 2, receives a high voltage from a power source 1, converts it into a low voltage, and transmits it to controllers that are load 3. For example, the voltage of the power source 1 is 48V, and the buck converter converts the voltage to 12V and transfers the converted voltage to the load 3.

However, if a short circuit fault occurs in the buck converter, the high voltage of the power source I cannot be converted into a low voltage and is output as it is, so if the high voltage is applied to the load 3, there is a risk that the load 3 may also be damaged.

The inventors of the present disclosure have been researching to overcome the problem that may affect load devices when the power conversion device of the related art fails. After much effort to provide a circuit device capable of protecting load devices even when the power conversion device fails using switching semiconductor devices, the present disclosure has been completed.

The present disclosure is directed to providing an apparatus capable of protecting load devices even when a power conversion device fails.

The present disclosure also aims to implement a protection circuit in the event of a power conversion device failure by a circuit as simple as possible without a complicated circuit configuration.

Meanwhile, other aspects not specified of the present disclosure will be additionally contemplated within the range that can be easily inferred from the following detailed description and effects thereof.

An apparatus for protecting circuit from power conversion device short circuit fault according to an embodiment of the present disclosure may include a first switch configured to connect a first node and a second node, wherein the first node is connected to an output of a power conversion device that converts a high voltage of a power supply into a low voltage, and wherein the third node is connected to a load; a first resistor configured to connect the first node and the second node, wherein a control voltage of the first switch is input to the second node; and a second resistor configured to connect the second node and a ground.

The first switch may be configured to connect the first node and the third node when the voltage of the second node is a low voltage, and open between the first node and the third node when the voltage of the second node is a high voltage.

The first switch may comprise a PMOS transistor, a source of the first switch may be connected to the first node, a drain of the first switch may be connected to the third node, and a gate of the first switch may be connected to the second node.

The first switch may comprise a CMOS transistor, a Vdd of the first switch may be connected to the first node, a Vss of the first switch may be connected to a ground, an input of the first switch may be connected to the second node, and an output of the first switch may be connected to the third node.

The converter may comprise a buck converter.

The ratio of the first resistor to the second resistor may be determined according to a voltage of the second node for controlling the first switch.

An apparatus for protecting circuit from power conversion device short circuit fault according to another embodiment of the present disclosure may include a first switch configured to connect a first node and a fifth node, wherein the first node is connected to an output of a power conversion device that converts a high voltage of a power supply into a low voltage, and wherein the fifth node is connected to a load; a third switch configured to connect a fourth node and a ground, wherein a control voltage of the first switch is input to the fourth node; a second switch configured to connect between a third node and the ground, wherein a control voltage of the third switch is input to the third node; and a plurality of resistors configured to connect the switches or the nodes.

The plurality of resistors may include a first resistor configured to connect the first node and the second node, wherein a control voltage of the second switch is input to the second node; a second resistor configured to connect the second node and the ground; a third resistor configured to connect the first node and the third node; a fourth resistor configured to connect the first node and the fourth node; and a fifth resistor configured to connect the fourth node and the third switch.

The ratio of the fourth resistor to the fifth resistor may be determined according to a voltage of the fourth node for controlling the first switch, and the ratio of the first resistor to the second resistor may be determined according to a voltage of the second node for controlling the second switch.

The first switch may be configured to connect the first node and the fifth node when the voltage of the fourth node is a low voltage, and open between the first node and the fifth node when the voltage of the fourth node is a high voltage, the third switch may be configured to connect the fourth node and the ground when the voltage of the third node is a high voltage, and open between the fourth node and the ground when the voltage of the third node is a low voltage, and the second switch may be configured to connect the third node and a ground when the voltage of the second node is a high voltage, and open between the third node and a ground when the voltage of the second node is a low voltage.

The first switch may comprise a PMOS transistor, a source of the first switch may be connected to the first node, a drain of the first switch may be connected to the fifth node, and a gate of the first switch may be connected to the fourth node.

The first switch may comprise a CMOS transistor, a Vdd of the first switch may be connected to the first node, a Vss of the first switch may be connected to the ground, an input of the first switch may be connected to the fourth node, and an output of the first switch may be connected to the fifth node.

The second switch and the third switch may comprise NMOS transistors; a drain of the second switch may be connected to the third node, a source of the second switch may be connected to the ground, and a gate of the second switch may be connected to the second node; and a drain of the third switch may be connected to a fifth resistor connected to the fourth node, a source of the third switch may be connected to the ground, and a gate of the third switch may be connected to the third node.

An apparatus for protecting circuit from power conversion device short circuit fault according to yet another embodiment of the present disclosure may include a first switch configured to connect a first node and a second node, wherein the first node is connected to an output of a power conversion device that converts a high voltage of a power supply into a low voltage, and wherein the second node is connected to a load; a sensor configured to measure a voltage of the first node; and a controller configured to control the first switch by the measured voltage of the sensor.

The controller may be configured to control the first switch to be a closed state when the voltage of the first node measured by the sensor is a normal voltage, and control the first switch to be an open state when the voltage of the first node measured by the sensor is an abnormal voltage.

The first switch may comprise a NMOS transistor or a PMOS transistor, and if the first switch is a NMOS transistor, the controller may be configured to apply a low voltage to a gate of the first switch when the voltage of the first node is abnormal, and if the first switch is a PMOS transistor, the controller may be configured to apply a high voltage to a gate of the first switch when the voltage of the first node is abnormal.

The first switch may comprise a CMOS transistor, and the controller may be configured to apply a low voltage to an input Vin of the first switch when the voltage of the first node is normal, and apply a high voltage to an input Vin of the first switch when the voltage of the first node is abnormal.

According to the present disclosure, load devices can be protected by blocking high voltage when a short circuit of the power conversion device fails.

In addition, by configuring a logic circuit with only semiconductor switches and resistor elements, high voltage can be cut off in the event of a power conversion device failure without complicated control to protect the circuit.

In the meantime, even if there is an effect not explicitly specified herein, it is added that the effects expected by the technical features of the present disclosure and described effects and provisional effects thereof in the following specification are regarded as described in the specification of the present disclosure.

### BRIEF DESCRIPTION OF THE SEVERAL VIEWS OF THE DRAWINGS

FIGS. 1 and 2 are schematic circuit diagrams of an apparatus for protecting circuit from power conversion device short circuit fault according to a preferred embodiment of the present disclosure.

FIGS. 3 and 4 are schematic circuit diagrams of an apparatus for protecting circuit from power conversion device short circuit fault according to another preferred embodiment of the present disclosure.

FIG. 5 is a schematic circuit diagram of an apparatus for protecting circuit from power conversion device short circuit fault according to yet another preferred embodiment of the present disclosure.

FIG. 6 is a schematic structural diagram of a circuit including a general power conversion device.

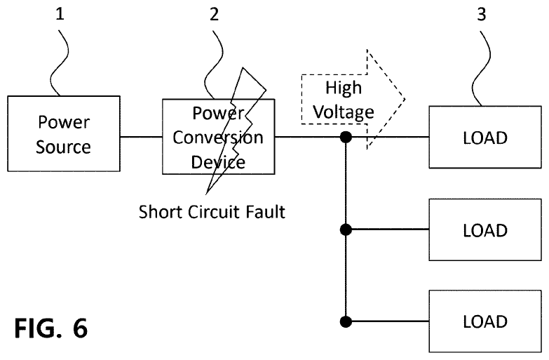

The accompanying drawings are exemplified by reference for understanding the technical idea of the present disclosure, and the scope of the present disclosure is not limited thereto.

### DETAILED DESCRIPTION

The above-mentioned objects, means, and effects thereof of the present disclosure will become more apparent from the following detailed description in relation to the accompanying drawings, and accordingly, those skilled in the art to which the present disclosure belongs will be able to easily practice the technical idea of the present disclosure. In addition, in describing the present disclosure, when it is determined that a detailed description of a related known technology may unnecessarily obscure the subject matter of the present disclosure, the detailed description will be omitted.

The terms used in this specification are for the purpose of describing embodiments only and are not intended to limit the present disclosure. In this specification, the singular forms “a,”, “an,” and “the” also include plural forms in some cases unless otherwise specified in the context. In this specification, terms such as “include”, “comprise”, “provide” or “have” do not exclude the presence or addition of one or more other elements other than elements mentioned.

In this specification, terms such as “or” and “at least one” may represent one of the words listed together or a combination of two or more thereof. For example, “A or B” and “at least one of A and B” may include only one of A or B, or may also include both A and B.

In this specification, descriptions according to “for example”, etc. may not exactly match the information presented, such as the recited properties, variables, or values, and effects such as modifications, including tolerances, measurement errors, limits of measurement accuracy, and other commonly known factors should not limit the modes for carrying out the disclosure according to the various exemplary embodiments of the present disclosure.

In this specification, when an element is described as being “connected” or “linked” to another element, it will be understood that it may be directly connected or linked to the other element but intervening elements may also be present. On the other hand, when an element is referred to as being “directly connected” or “directly linked” to another element, it will be understood that there are no intervening elements present.

In this specification, when an element is described as being “on” or “adjacent to” another element, it will be understood that it may be directly “on” or “connected to” the other element, but intervening elements may also be present. On the other hand, when an element is described as being “directly on” or “directly adjacent to” another element, it will be understood that there are no intervening elements present. Other expressions describing the relationship between the elements, for example, “between” and “directly between”, and the like can be construed similarly.

In this specification, terms such as “first” and “second” may be used to describe various elements, but, the above elements should not be limited by the terms above. In addition, the above terms should not be construed as limiting the order of each element, and may be used for the purpose of distinguishing one element from another. For example, a “first element” may be named as a “second element” and similarly, a “second element” may also be named as a “first element.”

Unless otherwise defined, all terms used in this specification may be used with meanings commonly understood by those of ordinary skill in the art to which the present disclosure belongs. In addition, terms defined in a commonly used dictionary are not interpreted ideally or excessively unless explicitly and specifically defined.

Hereinafter, a preferred embodiment according to the present disclosure will be described in detail with reference to the accompanying drawings.

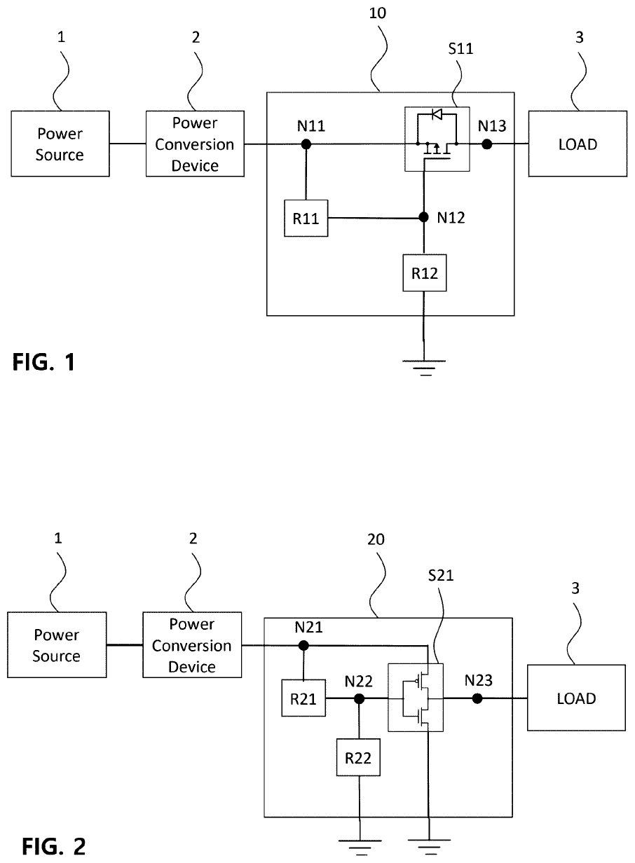

FIG. 1 is a schematic circuit diagram of an apparatus for protecting circuit from power conversion device short circuit fault according to a preferred embodiment of the present disclosure.

An apparatus 10 for protecting circuit from power conversion device short circuit fault according to the present disclosure may include a first switch S11, a first resistor R11, and a second resistor R12.

A power conversion device 2 is used to convert power from a power source 1. For example, it is used to convert types of power (such as alternating current or direct current, two or three phases), or to convert the magnitude of voltage or current.

For example, when the power conversion device 2 is a converter, high-voltage DC power may be converted into low-voltage DC power. For example, when the power conversion device 2 is an inverter, DC power may be converted into AC power.

In an embodiment of the present disclosure, the power conversion device 2 may be a buck converter, but is not limited thereto.

When a buck converter is used as the power conversion device 2, the high voltage of the power source 1 is converted into a low voltage. For example, a 48V DC voltage may be converted into a 12V DC voltage and supplied to the load 3.

The first switch S11 connects a first node N11 and a third node N13. The first node N11 is connected to the power conversion device 2 and the third node N13 is connected to the load 3.

Specifically, when the voltage of the first node N11 is normal (low voltage), the first switch S11 connects the first node N11 and the third node N13 to transmit the output of the power conversion device 2 to the load 3.

On the other hand, when the voltage of the first node N11 is abnormal (high voltage), the connection between the first node N11 and the third node N13 is cut off by opening between the first node N11 and the third node N13.

The first switch S11 may be a semiconductor switch controlled by the voltage of the second node N12. For example, the first switch S11 may be an NMOS transistor, a PMOS transistor, a CMOS transistor, or the like, but is not limited thereto. Although the first switch S11 is illustrated as a PMOS switch in the example of FIG. 1, it is not limited thereto.

The voltage of the second node N12 is determined to distribute the voltage of the first node N11 by the ratio of the first resistor R11 and the second resistor R12. For example, if the first resistor R11 and the second resistor R12 have the same value, the voltage of the second node N12 may be half of the voltage of the first node N11.

When the voltage of the second node N12 is controlled to the threshold voltage of the first switch S11 by adjusting the ratio of the first resistor R11 and the second resistor R12, the closing/opening of the first switch S11 may be adjusted by the voltage of the first node N11.

For example, the first switch S11 may be a semiconductor switch that is closed when the second node N12 is a low voltage and opened when the second node N12 is a high voltage. Therefore, when the power conversion device 2 normally outputs a low voltage, the second node N12 also becomes a low voltage and the first switch S11 becomes closed, so it connects the first node N11 and the third node N13. Conversely, when the power conversion device 2 is short-circuited due to a failure, the high voltage of the power source 1 is output to the first node N11 as it is. Then, since the second node N12 also becomes a high voltage and the first switch S11 becomes opened, between the first node N11 and the third node N13 are opened to block the high voltage supplied to the load 3 to protect the load 3.

In the example of FIG. 1, the first switch S11 may be a PMOS transistor among semiconductor switches. The PMOS transistor has the characteristic that the connection is cut off when the voltage applied to the gate is high voltage, and the connection is maintained when the voltage applied to the gate is low voltage.

Therefore, when the first switch S11 is a PMOS transistor, the gate voltage of the first switch S11 becomes the voltage of the second node N12, and when the voltage of the second node N12 is a normal voltage, that is, a low voltage, the first switch S11 is closed, and when the voltage of the second node N12 is an abnormal voltage, that is, a high voltage, the first switch S11 is opened. To this end, a gate of the PMOS transistor, which is the first switch S11, is connected to the second node N12, a source is connected to the first node N11, and a drain is connected to the third node N13.

FIG. 2 is a schematic circuit diagram of an apparatus for protecting circuit from power conversion device short circuit fault when CMOS is used as a switch element in accordance with a preferred embodiment of the present disclosure.

Unlike the example of FIG. 1, it represents an example in which a complementary metal oxide semiconductor (CMOS) transistor is used as the first switch S21.

A CMOS transistor is a transistor made up of a structure in which an NMOS transistor and a PMOS transistor are connected in a pair, consisting of an input Vin, an output Vout, Vdd, and Vss terminals. The CMOS transistor outputs Vdd as the output Vout when the input voltage Vin is a low voltage, and outputs Vss as the output Vout when the input voltage Vin is a high voltage. Thus, if Vss is connected to ground, it achieves the same effect as it is open.

In the example of FIG. 2, when a CMOS transistor is used as the first switch S21, the second node N22 is connected to the input Vin and the third node N23 is connected to the output Vout. The first node N21 is connected to the Vdd and the ground is connected to the Vss.

Therefore, when the voltage of the first node N21 is a normal voltage, that is, a low voltage, a low voltage is also applied to the second node N22, and the first switch S21, which is a CMOS transistor, outputs the voltage of the first node N21 that is Vdd to the third node N23.

When the voltage of the first node N21 is an abnormal voltage, that is, a high voltage, a high voltage is applied to the second node N22, and since the first switch S21, which is a CMOS transistor, connects the ground, which is Vss, to the third node N23, the voltage of the first node N21, which is an abnormal voltage, is not transmitted to the load 3 and is blocked.

In this way, when a CMOS transistor is used for the first switch S21, there is an advantage that the output voltage of the power conversion device 2 is transmitted to the load 3 through the first switch S21 without a voltage drop according to the CMOS transistor characteristics.

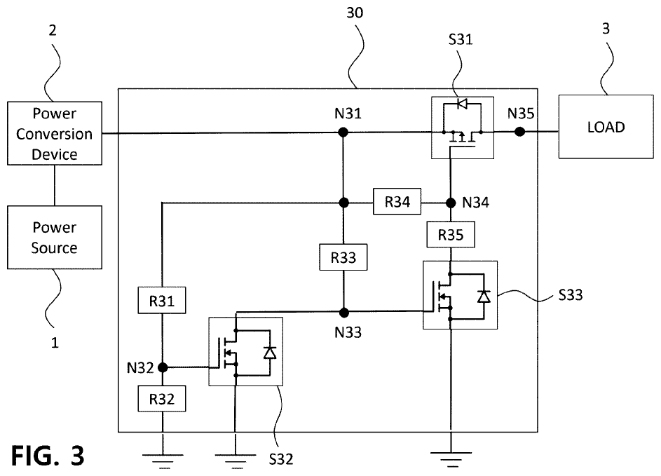

FIG. 3 is a schematic circuit diagram of an apparatus for protecting circuit from power conversion device short circuit fault according to another preferred embodiment of the present disclosure.

The apparatus 30 for protecting circuit from power conversion device short circuit fault according to the present disclosure may further include a second switch S32 and a third switch S33 for controlling the first switch S31 in addition to the first switch S31.

The first switch S31 controls the connection between a first node N31 which is an output of the power conversion device 2 and a fifth node N35 which is an output transmitted to the load 3.

The first switch S31 is controlled by the voltage of a fourth node N34, and the voltage of the fourth node N34 is controlled by a third switch S33. The third switch S33 is controlled by the third node N33, the voltage of the third node N33 is controlled by the second switch S32, and the voltage of the second switch S32 is controlled by a second node N32.

In an embodiment of FIG. 3, the first switch S31 may be a PMOS transistor, and the second switch S32 and the third switch S33 may be NMOS transistors. In this case, if the voltage of the fourth node N34 is a low voltage, the first switch S31 is in a closed state, and if the voltage of the fourth node N34 is a high voltage, the first switch S31 is in an open state. On the contrary, when the second node N32 and the third node N33 are in a high voltage, the second switch S32 and the third switch S33 are in a closed state, respectively, and when the second node N32 and the third node N33 are in a low voltage, the second node N32 and the third node N33 are in an open state, respectively. By a combination of these switches, the output voltage of the power conversion device 2 may be transmitted to or cut off from the load 3.

In this case, the source of the first switch S31 which is a PMOS transistor is connected to the first node N31, the drain is connected to the fifth node N35, and the gate is connected to the fourth node N34.

The drain of the second switch S32, which is an NMOS transistor, is connected to the third node N33, the source is connected to the ground, and the gate is connected to the second node N32.

Similarly, the drain of the third switch S32, which is an NMOS transistor, is connected to the fifth resistor R35, the source is connected to the ground, and the gate is connected to the third node N33.

The voltages of the fourth node N34, the second node N32, and the third node N33 respectively controlling the closing/opening of the first switch S31, the second switch S32, and the third switch S33 are controlled by a plurality of resistors.

The plurality of resistors may include a first resistor R31 between the first node N31 and the second node N32, a second resistor R32 between the second node N32 and the ground, a third resistor R33 between the first node N31 and the third node N33, a fourth resistor R34 between the first node N31 and the fourth node N34, and a fifth resistor R35 between the fourth node N34 and the third switch S33.

A voltage applied to each node may be adjusted according to a ratio between the plurality of resistors, and accordingly, a closing or opening of each switch is controlled.

Table 1 below shows the relationship between the output voltage of the power conversion device 2 and the voltage supplied to the load 3.

TABLE 1

| | Normal | Fault |
|---|---|---|
| N31 | 12 V | 48 V |
| N32 | L | H |
| N33 | H | L |
| N34 | L | H |
| N35 | 12 V | X |

The power conversion device 2 may be, for example, a buck converter, and the buck converter converts a high voltage (48V) of the power source 1 into a low voltage (12V) and outputs the low voltage.

When the buck converter is normal, the voltage of the first node N31, which is the output voltage of the power conversion device 2, becomes 12V which is the low voltage.

When the voltage of the first node N31 is 12V, the voltage of the second node N32 becomes a low voltage L, and thus the second switch S32, which is an NMOS transistor controlled by the second node N32, is in an open state.

When the second switch S32 is in an open state, the voltage of the third node N33 becomes a high voltage H, and thus the third switch S33, which is an NMOS transistor controlled by the third node N33, is in a closed state.

When the third switch S33 is in a closed state, the fifth resistor R35 is connected to the ground, and the voltage of the fourth node N34 becomes a low voltage L according to the voltage distribution between the fourth resistor R34 and the fifth resistor R35.

Since the first switch S31 controlled by the fourth node N34 is a PMOS transistor, when the fourth node N34 is a low voltage L, the first switch S31 is in a closed state, and thus a 12V voltage, which is an output of the power conversion device 2, is transmitted to the load 3.

On the contrary, when the buck converter, which is the power conversion device 2, fails with a short circuit, a 48V voltage, which is a high voltage of the power source 1, is output to the first node N31 as it is.

When the voltage of the first node N31 is 48V, the voltage of the second node N32 becomes a high voltage H by voltage distribution between the first resistor R31 and the second resistor R32.

When the voltage of the second node N32 is a high voltage H, the second switch S32, which is an NMOS transistor controlled by the second node N32, is in a closed state, and thus the third node N33 is connected to the ground to become a low voltage L state.

When the voltage of the third node N33 is a low voltage L, the third switch S33, which is an NMOS transistor controlled by the third node N33, becomes an open state, and thus the fourth node N34 becomes a high voltage H state.

When the fourth node N34 is in a high voltage H state, the first switch S31 controlled by the voltage of the fourth node N34 is a PMOS transistor, and thus is in an open state when the gate voltage is a high voltage. Therefore, the high voltage 48V of the first node N31 is blocked without being transferred to the fifth node N35.

FIG. 4 illustrates an example of using a CMOS transistor as the first switch in the example of FIG. 3.

The second switch S42 and the third switch S43 may be NMOS transistors as in the example of FIG. 3, and the connection relationship with other nodes and resistors is the same as in the example of FIG. 3.

Since the first switch S41 is a CMOS transistor, it is not composed of source, drain, and gate terminals, but is composed of input Vin, output Vout, Vdd, and Vss terminals.

In the example of FIG. 4, the input Vin of the first switch S41 is connected to the fourth node N44, and the output Vout is connected to the fifth node N45 and is connected to the load 3. In addition, the power source voltage Vdd is connected to the first node N41, and Vss is connected to the ground.

If the first switch S41 is a CMOS transistor, when the input Vin is a low voltage L, the voltage of the first node N41 that is Vdd is output, and when the input Vin is a high voltage H, the ground that is Vss is connected to the fifth node N45, and thus the voltage of the first node N41 is cut off.

Therefore, as in the example of FIG. 3, when the voltage of the first node N41 is a normal voltage 12V, the voltage of the fourth node N44 becomes a low voltage L, and thus the output Vout of the first switch S41 becomes the voltage of the first node N41 that is Vdd, so the normal output 12V of the buck converter, which is the power conversion device 2, is transferred to the load 3 through the output Vout of the first switch S41.

On the other hand, when the voltage of the first node N41 is 48V, which is an abnormal voltage, the voltage of the fourth node N44 becomes a high voltage H, and the output Vout of the first switch S41 is connected to the ground Vss, so that the fifth node N45 is connected to the ground to block the abnormal high voltage of the first node N41 from being transmitted to the load 3.

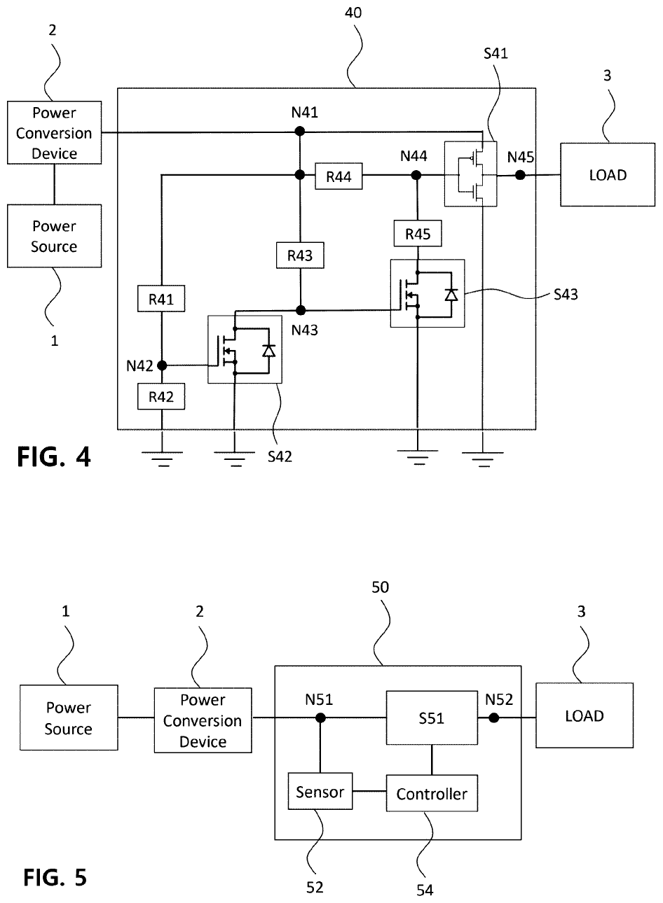

FIG. 5 is a schematic circuit diagram of an apparatus for protecting circuit from power conversion device short circuit fault according to yet another preferred embodiment of the present disclosure.

An apparatus 50 for protecting circuit from power conversion device short circuit fault according to the present disclosure may include a first switch S51, a sensor 52, and a controller 54.

The first switch S51 connects the first node N51, which is an output of the power conversion device 2, and the second node N52 connected to the load, and a closing or opening may be controlled by the controller 54.

To this end, the controller 54 may be configured to include one or more processors and memory.

The controller 54 may measure the voltage of the first node N51 through the sensor 52 and control the closed or open state of the first switch S51 accordingly.

For example, if the first switch S51 is a PMOS transistor, when the voltage of the first node N51 is a normal voltage, the controller 54 may transmit the voltage of the first node N51 to the load 3 through the second node N52 by closing the first switch S31 by applying a low voltage to the gate of the first switch S51. On the other hand, when the voltage of the first node N51 is an abnormal voltage, the controller 54 may apply a high voltage to the gate of the first switch S51 to open the first switch S51, thereby controlling the voltage of the first node N51 not to be transmitted to the second node N52.

Alternatively, if the first switch S51 is a CMOS transistor, when the voltage of the first node N51 is a normal voltage, the controller 54 may apply a low voltage to the input Vin of the first switch S51 and when the voltage of the first node N51 is an abnormal voltage, the controller 34 may apply a high voltage to the input Vin of the first switch S51, thereby transmitting or blocking the voltage of the first node N51 to the load 3.

On the contrary, if the first switch S51 is an NMOS transistor, when the voltage of the first node N51 is a normal voltage, the controller 34 may apply a high voltage to the gate of the first switch S51 to close the first switch S51, thereby transmitting the voltage of the first node N51 to the load 3 through the second node N52. On the other hand, when the voltage of the first node N51 is an abnormal voltage, the controller 54 may apply a low voltage to the gate of the first switch S51 to open the first switch S51, thereby controlling the voltage of the first node N51 not to be transmitted to the second node N52. That is, the controller 54 controls the closing and opening of the first switch S51 by applying a high voltage and a low voltage to the gate of the NMOS transistor, contrary to the case of the PMOS transistor.

When the apparatus 50 for protecting circuit from power conversion device short circuit fault is configured by the controller 54 and the sensor 52 as such, there is an advantage that the controller 54 can control the switch by generating an appropriate control signal regardless of the type of switch.

As such, according to the apparatus for protecting circuit from power conversion device short circuit fault according to the present disclosure, even if an unexpected high voltage is output due to a failure of the power conversion device, various control devices connected to the load can be protected by effectively blocking it and controlling it not to be transmitted to the load.

In the detailed description of the present disclosure, although specific embodiments have been described, it is apparent that various modifications are possible without departing from the scope of the present disclosure. Therefore, the scope of the present disclosure is not limited to the described embodiments, and should be defined by the following claims and their equivalents.

1. An apparatus for protecting circuit from power conversion device short circuit fault, the apparatus comprising:
a switch having a control node configured to disconnect a load from the power conversion device when a short circuit fault occurs in the power conversion device;
a first resistor; and
a second resistor configured to the switch and a ground;
wherein the first resistor and second resistors are disposed in a way that a first voltage applied by the power conversion device is distributed according to the ratio of the first resistor to the second resistor, and a second voltage applied to the control node is proportional to the ratio.

2. The apparatus of claim 1,
wherein the switch is configured to disconnect the load from the power conversion device when the second voltage is higher than a threshold, the threshold is a basis for opening the switch.

3. The apparatus of claim 1, wherein the switch comprises a PMOS transistor, the second voltage applied to a gate of the first switch.

4. The apparatus of claim 1, wherein the switch comprises a CMOS transistor, and wherein the second voltage is applied both to control nodes of a PMOS and NMOS in the CMOS for controlling the CMOS, and the PMOS is configured to connect the load to the power conversion device and the NMOS is configured to connect the load to the ground.

5. The apparatus of claim 1, wherein the power conversion device comprises a buck converter.

6. The apparatus of claim 1, wherein the ratio of the first resistor to the second resistor is determined according to the threshold.

7. An apparatus for protecting circuit from power conversion device short circuit fault, the apparatus comprising:
a first switch having a first control node, configured to disconnect a load from the power conversion device when a short circuit fault occurs in the power conversion device;
a second switch having a second control node, configured to connect a third control node to a ground when a short circuit fault occurs in the power conversion device;
a third switch having the third control node, configured to disconnect the first control node from the ground when a short circuit fault occurs in the power conversion device; and
first to fifth resistors;
wherein the first and second resistors are disposed in a way that a first voltage applied by the power conversion device is distributed according to the first ratio of the first resistor to the second resistor, and a second voltage applied to the second control node is proportional to the first ratio,
wherein the fourth and fifth resistors are disposed in a way that a first voltage applied by the power conversion device is distributed according to the second ratio of the fourth resistor to the fifth resistor, and a third voltage applied to the first control node is proportional to the second ratio.

8. The apparatus of claim 7,
wherein the third resistor is disposed in a way that a fourth voltage is applied to the third switch when a short circuit fault does not occur in the power conversion device, the fourth voltage is the voltage dropped from the first voltage by the third resistor.

9. The apparatus of claim 8,
wherein the first ratio is determined corresponding to a first threshold of the second switch, the first threshold is a basis for closing the second switch,
wherein the second ratio is determined corresponding to a second threshold of the first switch, the second threshold is a basis for opening the first switch.

10. The apparatus of claim 8,
wherein the first switch is configured to connect a load to a power conversion device, the second switch is configured to disconnect the third control node from a ground and the third switch is configured to connect the first control node to the ground, before the short circuit.

11. The apparatus of claim 7, wherein the first switch comprises a PMOS transistor.

12. The apparatus of claim 7,
wherein the first switch comprises a CMOS transistor, and
wherein the third voltage is applied both to control nodes of a PMOS and NMOS in the CMOS for control the CMOS and the PMOS is configured to connect the load from the power conversion device and the NMOS is configured to connect the load from the ground.

13. The apparatus of claim 11,
wherein the second switch and the third switch comprise NMOS transistors.

14. The apparatus of claim 7, wherein the power conversion device comprises a buck converter.

15. An apparatus for protecting circuit from power conversion device short circuit fault, the apparatus comprising:
a switch configured to disconnect a load from a power conversion device when a short circuit fault occurs in the power conversion device short;
a sensor configured to measure an output voltage of the power conversion device; and
a processor configured to control the switch based on the output voltage.

16. The apparatus of claim 15,
wherein the processor is configured to:
control the switch to be a closed state when the output voltage is abnormal.

17. The apparatus of claim 15,
wherein the switch comprises a NMOS transistor, and
wherein the processor is configured to apply a control voltage to a gate of the switch when the output voltage of is abnormal, the control voltage is lower than the threshold of the switch.

18. The apparatus of claim 15,
wherein the switch comprises a PMOS transistor, and
wherein the processor is configured to apply a control voltage to a gate of the switch when the output voltage of is abnormal, the control voltage is higher than the threshold of the switch.

19. The apparatus of claim 15,
wherein the switch comprises a CMOS transistor, and
wherein the processor is configured to apply a control voltage both to control nodes of a PMOS an NMOS in the CMOS for controlling the CMOS, and the PMOS is configured to connect the load from the power conversion device and the NMOS is configured to connect the load from the ground, the control voltage is higher than the threshold of both the PMOS and the NMOS, when the output voltage is abnormal.

20. The apparatus of claim 15, wherein the power conversion device comprises a buck converter.
